(19) United States
(12) Patent Application Publication
(10) Pub. No.: US 2026/0075726 A1
(43) Pub. Date: Mar. 12, 2026

(54) ROUTER POWER SUPPLY SUPPORT RACK

(71) Applicant: Xue-feng Chen, Guangzhou City (CN)

(72) Inventor: Xue-feng Chen, Guangzhou City (CN)

(21) Appl. No.: 18/830,593

(22) Filed: Sep. 11, 2024

(51) Int. Cl. H05K 5/02; F16M 13/02

(52) U.S. Cl. CPC H05K 5/0204; F16M 13/02

(57) ABSTRACT

A router power supply support rack includes a main frame having a first limiting portion and an elastic pressing member. A first space is formed between the elastic pressing member and the first limiting portion. A power supply frame is connected to a bottom of the main frame and has a side limiting portion and a side elastic pressing portion on two sides thereof. The power supply frame includes an upper limiting member and a lower limiting member. A second space is formed between the side limiting portion, the side elastic pressing portion, the upper limiting member, and the lower limiting member. A first tube having a through-hole is connected to the power supply frame and located opposite to the second space. The router power supply support rack is installed on a wall without occupying floor space.

### BACKGROUND OF THE INVENTION

### 1. Fields of the Invention

The present invention relates to a router power supply support rack to accommodate a router and its power supply.

### 2. Descriptions of Related Art

Routers are widely used in homes to provide network signals, with some models even having signal enhancement capabilities. To provide internet access, routers need to be combined with other equipment to build a complete system. Taking the Starlink router as an example, it includes a satellite dish, a main unit, and a power supply. The main unit is connected between the satellite dish and the power supply. The advantage is that regardless of the user's location, as long as the satellite dish is not obstructed, users can obtain stable network speeds at any time.

When setting up a Starlink router, the satellite dish is generally installed outdoors, such as on the household roof, and should be free from any obstructions. The main unit and power supply only need to be set up indoors. However, there are many inconveniences in storing the main unit and power supply. For example, since the main unit and power supply are connected by a power cable, they must be placed in the same location, which occupies a relatively large flat space. Furthermore, the length of the cables between the main unit and power supply can create visual clutter.

In order to improve the storage problem of the conventional Starlink router's main unit and power supply indoors, the present invention can be mounted on a wall during actual installation. It includes a main frame for storing the main unit and a power supply frame for storing the power supply. This way, users can place the main unit and power supply on this wall-mounted invention without occupying floor space. Furthermore, on the side facing the wall, the present invention has a first tube for winding the cables between the main unit and power supply. This prevents excessive exposure of cables between the main unit and power supply, which would otherwise cause visual clutter. Therefore, the present invention indeed improves the storage problem of the conventional Starlink router's main unit and power supply.

### SUMMARY OF THE INVENTION

The present invention relates to a router power supply support rack and comprises a main frame having a first limiting portion and an elastic pressing member located on a top thereof. A first space is formed between the elastic pressing member and the first limiting portion. A power supply frame is connected to a bottom of the main frame and comprises a side limiting portion on one of two sides of the power supply frame, and a side elastic pressing portion on another one of the two sides of the power supply frame. An upper limiting member is located on a top edge of the power supply frame, and a lower limiting member is located on a bottom edge of the power supply frame. A second space is formed between the side limiting portion, the side elastic pressing portion, the upper limiting member, and the lower limiting member. A first tube is connected to the power supply frame and located opposite to the second space. The first tube has second tube formed therein, and the second tube has a through-hole.

Preferably, multiple main structure reinforcing ribs are connected between the main frame and the power supply frame.

Preferably, a thickness of the multiple main structure reinforcing ribs decreases in a direction away from the first tube. The multiple main structure reinforcing ribs slopes upward from a bottom to a top thereof so as to present a triangular shape.

Preferably, the multiple main structure reinforcing ribs are arranged in groups of three.

Preferably, the upper limiting member has multiple upper reinforcing ribs arranged at intervals inside.

Preferably, the lower limiting member has multiple lower reinforcing ribs arranged at intervals inside.

Preferably, the pressing member has a flap extending from a direction opposite to the first space.

Preferably, the main frame has a second limiting portion on the top thereof. The first limiting portion includes a first L-structure and a first triangular structure connected by bending. The second limiting portion includes a second L-structure and a second triangular structure connected by bending. The first triangular structure and the second triangular structure extend towards each other.

Preferably, the main frame includes grooves which are located on both sides of the pressing member.

Preferably, multiple flange are connected between the second tube that has the through-hole and a periphery of the first tube.

The primary object of the present invention is to provide a router power supply support rack which can be mounted on the wall during actual installation. The router power supply support rack includes a main frame for storing the main unit and a power supply frame for storing the power supply. This allows users to place the main unit and power supply on this wall-mounted invention without occupying floor space. Furthermore, on the side facing the wall, the router power supply support rack has a first tube for winding the cables between the main unit and the power supply. This prevents excessive exposure of cables between the main unit and power supply, which would otherwise cause visual clutter. Therefore, the present invention indeed improves the storage problem of conventional Starlink router's main unit and power supply, and thus possesses novelty and inventiveness.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 is a perspective view of the present invention;

FIG. 2 is another perspective view of the present invention;

FIG. 3 is yet another perspective view of the present invention;

FIG. 4 is a side view of the present invention;

FIG. 5 shows an illustration of the present invention mounted on a wall;

FIG. 6 is a side view to show that the present invention is mounted on a wall;

FIG. 7 shows an illustration of the present invention with power supply and main unit installed;

FIG. 8 shows an illustration of the cables between the power supply and main unit wound around the first tube for storage;

FIG. 9 is a side view to illustrate the cables, between the power supply and main unit, wound around the first tube for storage;

FIG. 10 is a top view to show the cables, between the power supply and main unit, wound around the first tube for storage, and

FIG. 11 is a front view illustration of the cables, between the power supply and main unit, wound around the first tube for storage.

### DETAILED DESCRIPTION OF THE PREFERRED EMBODIMENT

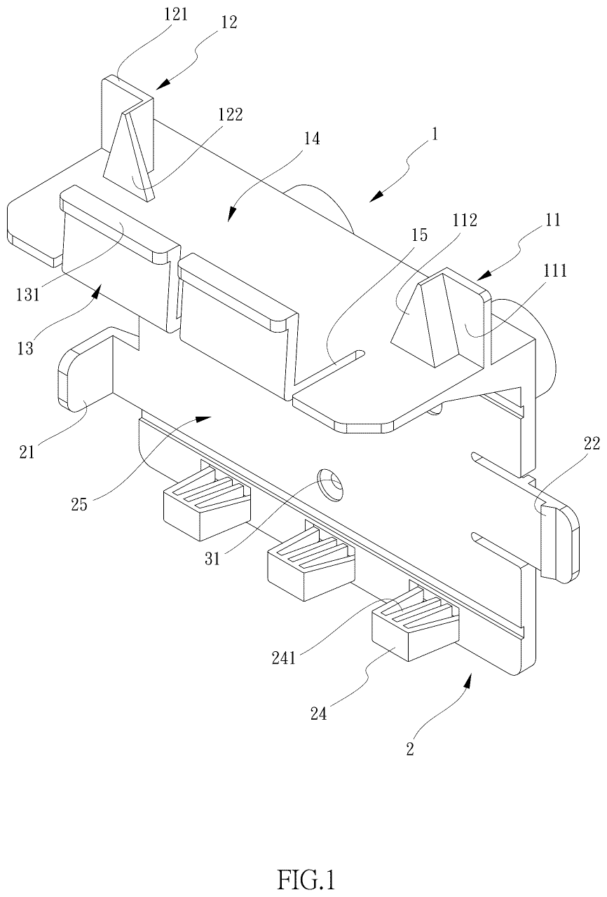

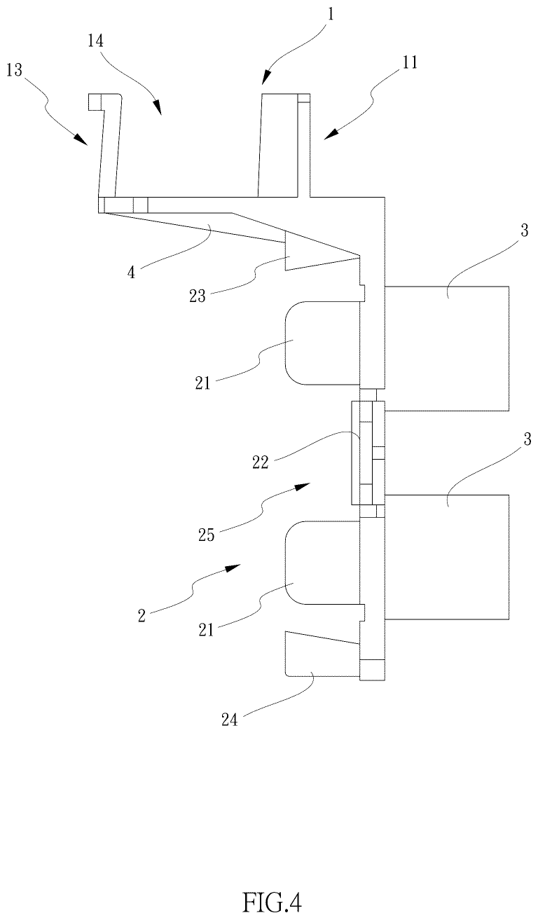

Referring to FIGS. 1 to 4, the router power supply support rack of the present invention comprises a main frame (1) having a first limiting portion (11) and an elastic pressing member (13) located on a top thereof. A first space (14) is formed between the elastic pressing member (13) and the first limiting portion (11). A power supply frame (2) is connected to a bottom of the main frame (1) and comprises a side limiting portion (21) on one of two sides of the power supply frame (2), and a side elastic pressing portion (22) on another one of the two sides of the power supply frame (2). An upper limiting member (23) is located on a top edge of the power supply frame (2), and a lower limiting member (24) is located on a bottom edge of the power supply frame (2). A second space (25) is formed between the side limiting portion (21), the side elastic pressing portion (22), the upper limiting member (23), and the lower limiting member (24). A first tube (3) is connected to the power supply frame (2) and located opposite to the second space (25). The first tube (3) has a second tube formed centrally therein and the second tube has a through-hole (31). In this embodiment, there are three first tubes (3).

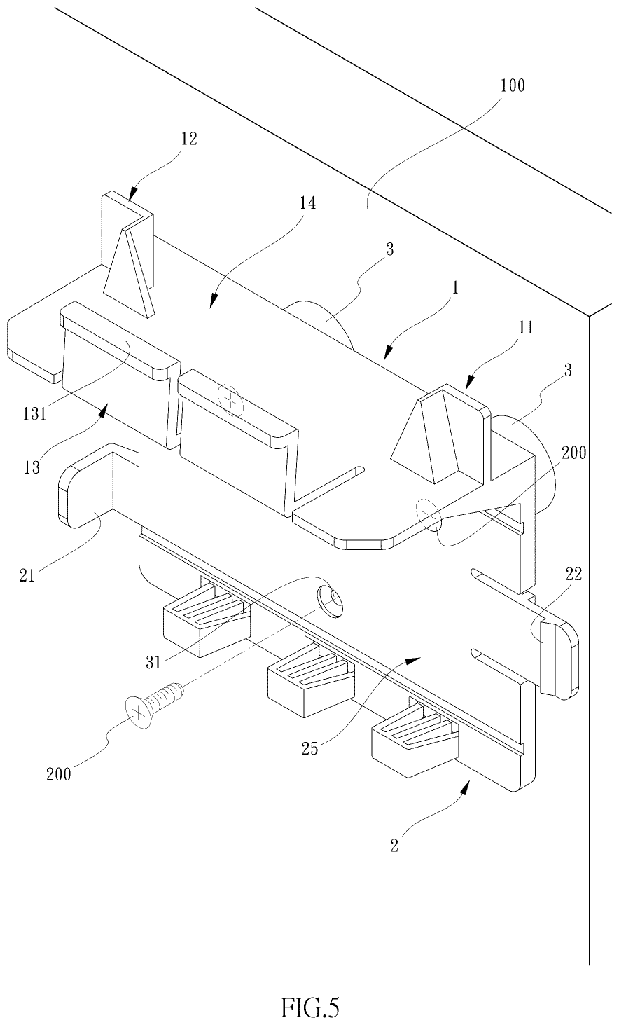

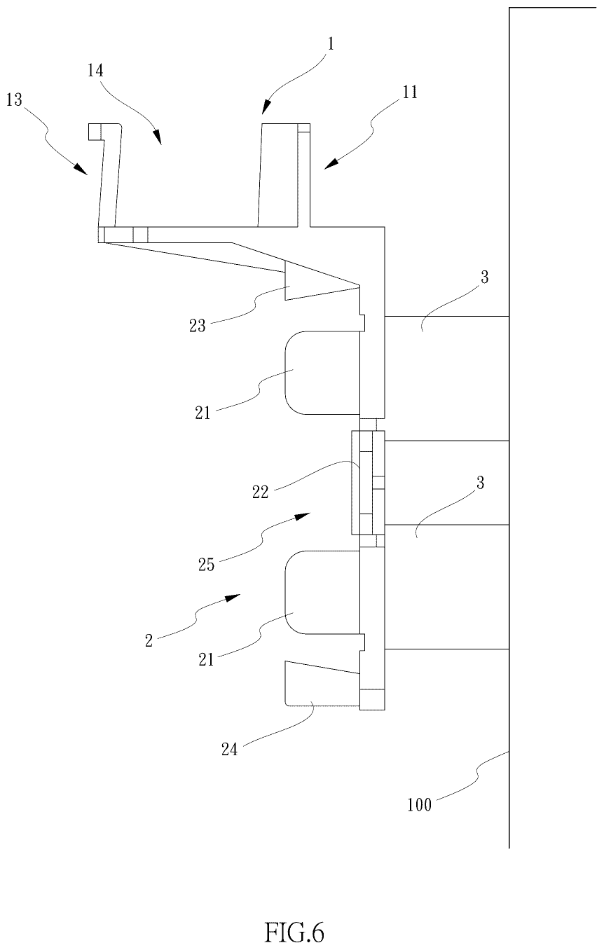

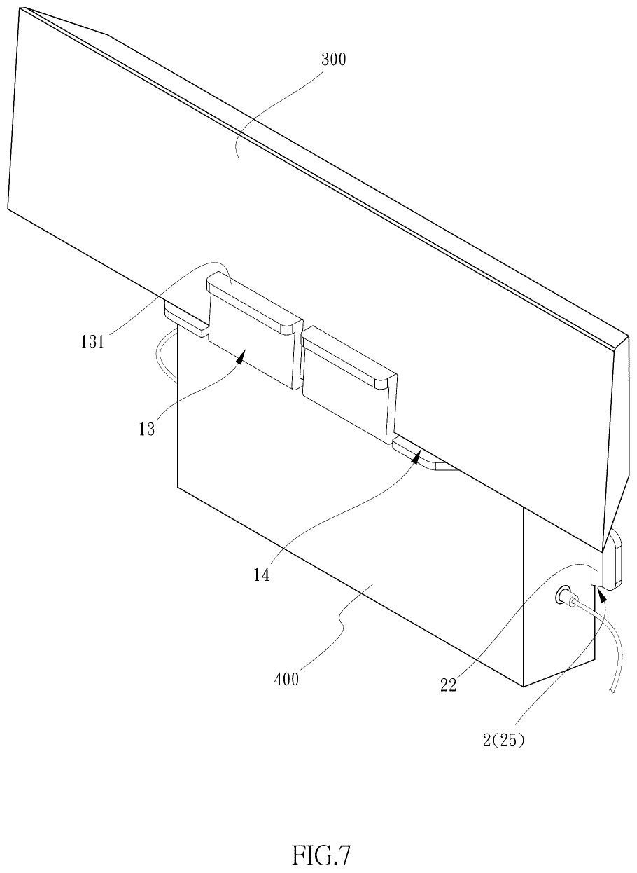

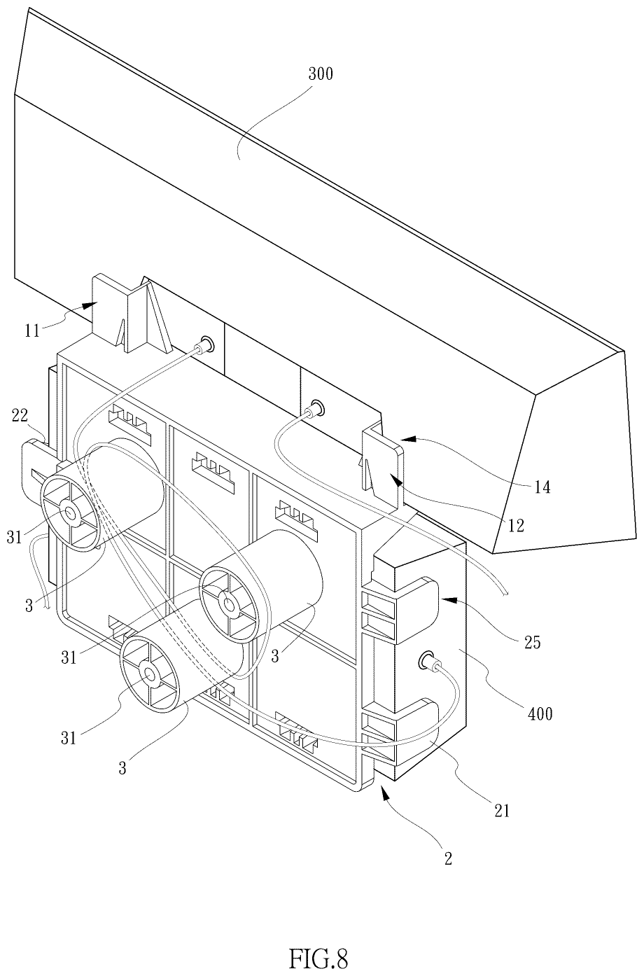

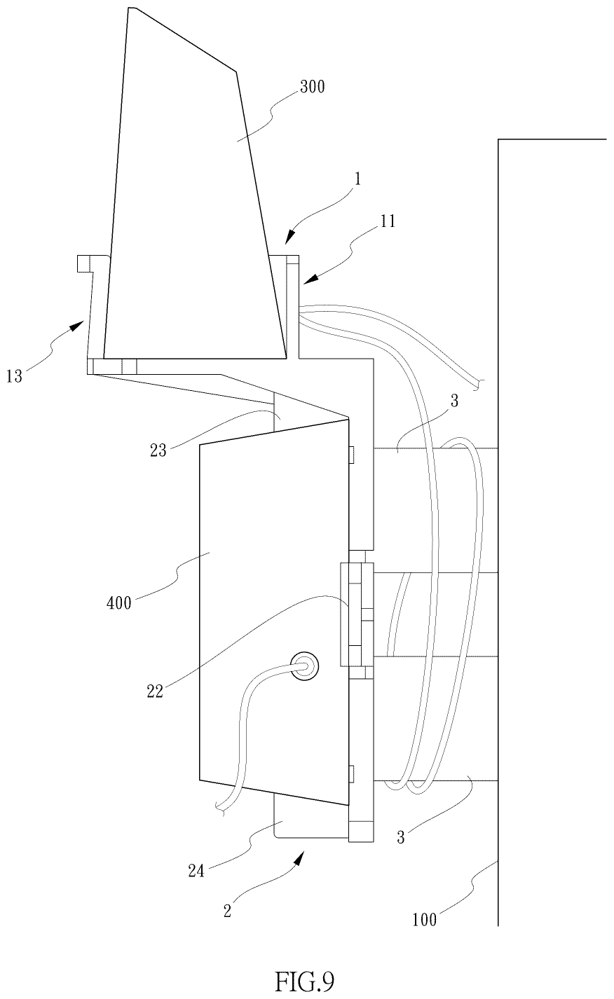

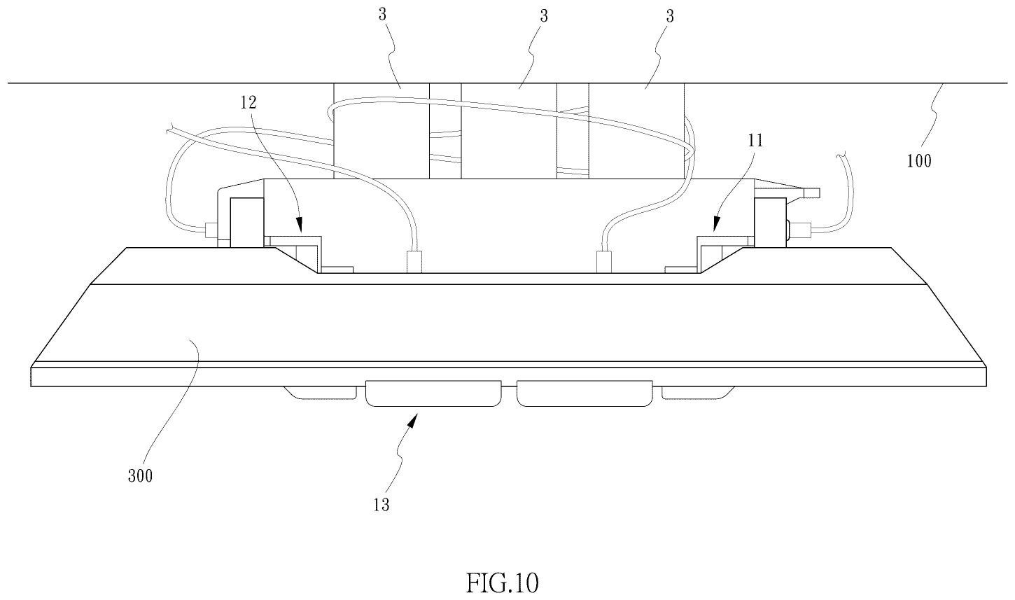

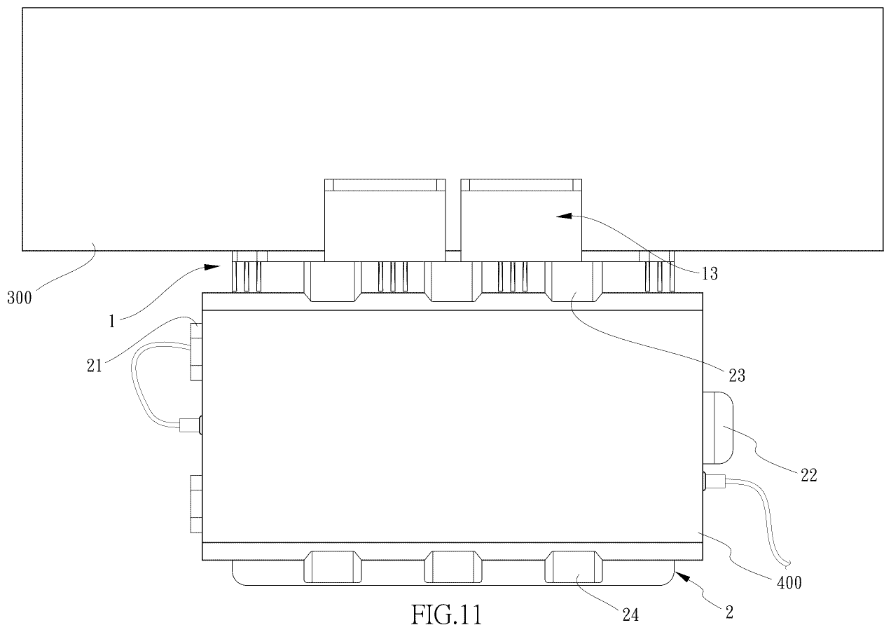

To improve the storage problem of the conventional Starlink router main unit and power supply indoors, the present invention can be mounted on a wall by using screws (200) as shown in FIGS. 5 and 6. The main frame (1) is capable of clamping the main unit (300) by using the first limiting portion (11) and the pressing member (13) so as to store the main unit (300) in the first space (14). The power supply frame (2) is capable of positioning by using the upper limiting member (23) and lower limiting member (24). The side limiting portion (21) and the side elastic pressing portion (22) clamp the power supply (400) so as to store the power supply (400) in the second space (25). By this way, users can place the main unit (300) and power supply (400) on this wall-mounted invention without occupying floor space (as shown in FIG. 7). Furthermore, on the side facing the wall, the present invention has a first tube (3) for winding the cables between the main unit (300) and power supply (400) (cable winding around first tube (3) is shown in FIGS. 8 to 11). The present prevents excessive exposure of cables between the main unit (300) and power supply (400), which would otherwise cause visual clutter. Therefore, the present invention indeed improves the storage problem of the conventional Starlink router's main unit (300) and power supply (400), and thus possesses novelty and inventiveness.

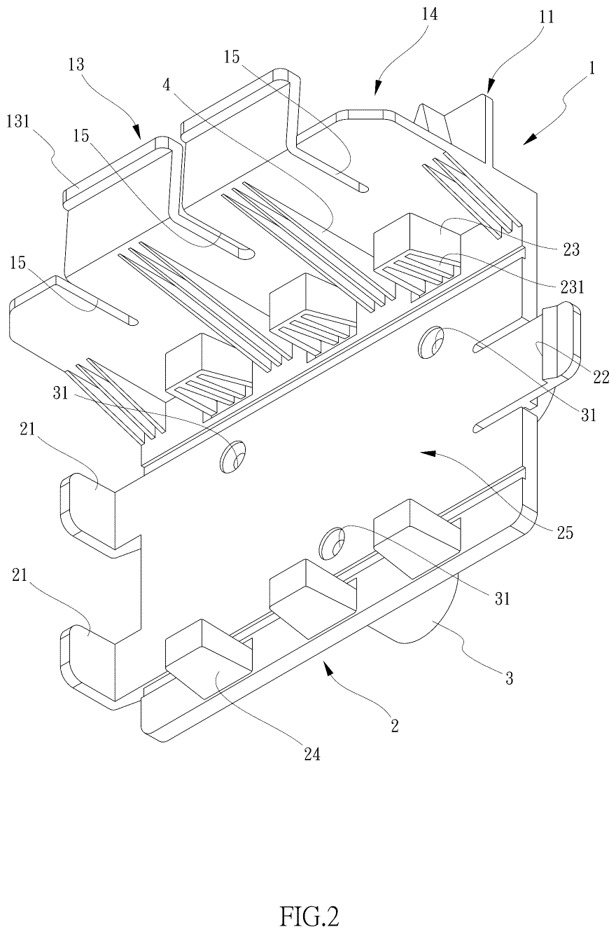

As shown in FIG. 2, multiple main structure reinforcing ribs (4) are connected between the main frame (1) and the power supply frame (2).

Preferably, a thickness of the multiple main structure reinforcing ribs (4) decreases in a direction away from the first tube (3). The multiple main structure reinforcing ribs (4) slopes upward from a bottom to a top thereof so as to present a triangular shape. Preferably, the multiple main structure reinforcing ribs (4) are arranged in groups of three so as to reduce the possibility of downward bending of the main frame (1) due to the weight of the main unit (300).

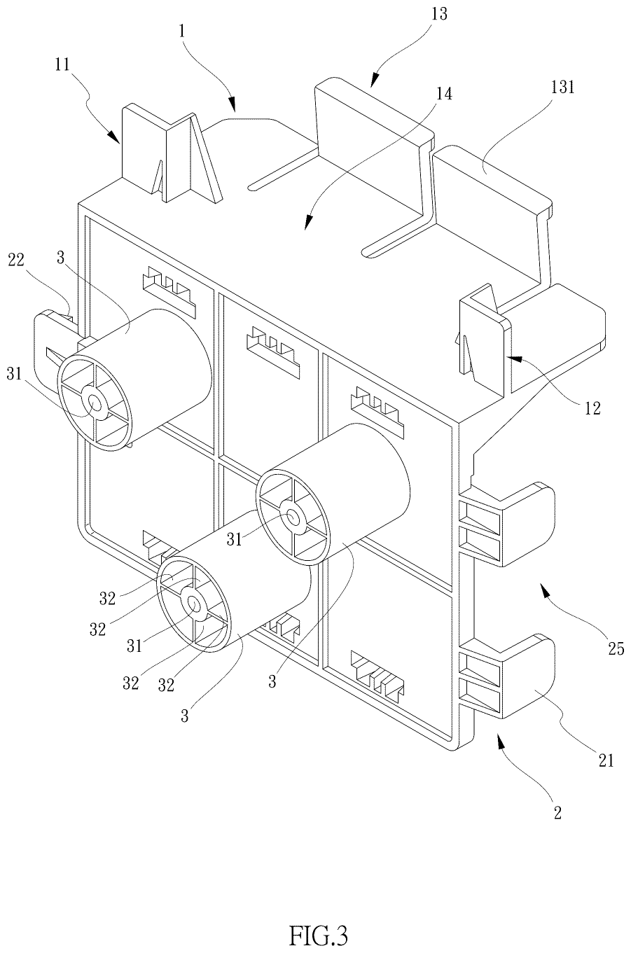

As shown in FIGS. 1 and 3, the upper limiting member (23) has multiple upper reinforcing ribs (231) arranged at intervals inside. The lower limiting member (24) has multiple lower reinforcing ribs (241) arranged at intervals inside. Therefore, the upper limiting member (23) lower limiting member (24) are reinforced.

As shown in FIG. 1, the pressing member (13) has a flap (131) extending from a direction opposite to the first space (14). The flap (131) assists users in applying force more effectively to flip the pressing member (13) outward.

The main frame (1) has a second limiting portion (12) on the top thereof. The first limiting portion (11) includes a first L-structure (111) and a first triangular structure (112) connected by bending. The second limiting portion (12) includes a second L-structure (121) and a second triangular structure (122) connected by bending. The first triangular structure (112) and the second triangular structure (122) extend towards each other. This structure provides better structural strength of the first and second limiting portions (11, 12).

As shown in FIGS. 1 and 2, the main frame (1) includes grooves (15) which are located on both sides of the pressing member (13). In this embodiment, there are two pressing member (13) to allow users to flip the pressing member (13) outward easily when adjusting the main unit (300). Multiple flange (32) are connected between the second tube that has the through-hole (31) and a periphery of the first tube (3).

While we have shown and described the embodiment in accordance with the present invention, it should be clear to those skilled in the art that further embodiments may be made without departing from the scope of the present invention.

What is claimed is:

1. A router power supply support rack, comprising:
a main frame (1) having a first limiting portion (11) and an elastic pressing member (13) located on a top thereof, a first space (14) formed between the elastic pressing member (13) and the first limiting portion (11), and
a power supply frame (2) connected to a bottom of the main frame (1), the power supply frame (2) comprising a side limiting portion (21) on one of two sides of the power supply frame (2), and a side elastic pressing portion (22) on another one of the two sides of the power supply frame (2), an upper limiting member (23) located on a top edge of the power supply frame (2), a lower limiting member (24) located on a bottom edge of the power supply frame (2), a second space (25) formed between the side limiting portion (21), the side elastic pressing portion (22), the upper limiting member (23), and the lower limiting member (24), a first tube (3) connected to the power supply frame (2) and located opposite to the second space (25), the first tube (3) having a second tube that has a through-hole (31).

2. The router power supply support rack as claimed in claim 1, wherein multiple main structure reinforcing ribs (4) are connected between the main frame (1) and the power supply frame (2).

3. The router power supply support rack as claimed in claim 2, wherein a thickness of the multiple main structure reinforcing ribs (4) decreases in a direction away from the first tube (3), the multiple main structure reinforcing ribs (4) slopes upward from a bottom to a top thereof so as to present a triangular shape.

4. The router power supply support rack as claimed in claim 3, wherein the multiple main structure reinforcing ribs (4) are arranged in groups of three.

5. The router power supply support rack as claimed in claim 1, wherein the upper limiting member (23) has multiple upper reinforcing ribs (231) arranged at intervals inside.

6. The router power supply support rack as claimed in claim 1, wherein the lower limiting member (24) has multiple lower reinforcing ribs (241) arranged at intervals inside.

7. The router power supply support rack as claimed in claim 1, wherein the pressing member (13) has a flap (131) extending from a direction opposite to the first space (14).

8. The router power supply support rack as claimed in claim 1, wherein of the main frame (1) has a second limiting portion (12) on the top thereof, the first limiting portion (11) includes a first L-structure (111) and a first triangular structure (112) connected by bending, the second limiting portion (12) includes a second L-structure (121) and a second triangular structure (122) connected by bending, the first triangular structure (112) and the second triangular structure (122) extend towards each other.

9. The router power supply support rack as claimed in claim 1, wherein the main frame (1) includes grooves (15) which are located on both sides of the pressing member (13).

10. The router power supply support rack as claimed in claim 1, wherein multiple flange (32) are connected between the second that has the through-hole (31) and a periphery of the first tube (3).
